(19) United States
(12) Patent Application Publication
(10) Pub. No.: US 2024/0069070 A1
(43) Pub. Date: Feb. 29, 2024

(54) DE-SKEW METHOD FOR DYNAMIC TESTING USING TRANSFER FUNCTION OF CURRENT SENSOR

(71) Applicant: Keysight Technologies, Inc., Santa Rosa, CA (US)

(72) Inventor: Takamasa Arai, Hachioji (JP)

(21) Appl. No.: 18/214,063

(22) Filed: Jun. 26, 2023

Related U.S. Application Data
(60) Provisional application No. 63/400,775, filed on Aug. 25, 2022.

(51) Int. Cl. G01R 13/02

(52) U.S. Cl. CPC G01R 13/0218

(57) ABSTRACT

A dynamic test method includes configuring a dynamic test set-up for a device under test (DUT), the dynamic test set-up including at least one de-skewed voltage probe and at least one de-skewed current measurement cable connected to respective channels of an oscilloscope, and a current sensor connected to the de-skewed current measurement cable and configured to measure a current of the DUT. The method further includes conducting a dynamic test set-up for the DUT using the dynamic test set-up to obtain a current waveform for display on the oscilloscope, and applying a transfer function of the current sensor to the current waveform to display a corresponding de-embedded current waveform on the oscilloscope.

### CROSS-REFERENCE TO RELATED APPLICATIONS

The present application claims priority under 35 U.S.C. § 119(e) to U.S. Provisional Application No. 63/400,775, filed on Aug. 25, 2022. The entire disclosures of U.S. Provisional Application No. 63/400,775 is specifically incorporated herein by reference in its entirety.

### BACKGROUND

Skew refers to propagation delay differences between probes and/or channels in oscilloscopes which may affect timing measurement accuracy. When characterizing dynamic parameters of power semiconductor devices, compensating the skew between Vds (or Vce) and Ids (or Ice) measurement channels of the oscilloscope is always important because it affects the accuracy of switching loss parameters significantly. Several skew compensation (de-skew) methods have been proposed so far as described in a publication entitled “Methodology for Wide Bandgap Device Dynamic Characterization” (Zheyu Zhang, IEEE Transactions on Power Electronics, Volume: 32, Issue: 12, December 2017, URL: https://ieeexplore.ieee.org/document/7827079), the disclosure of which is incorporated herein by reference in its entirety. However, all the described methods have pros and cons. That is, as explained below, each requires a special fixture, modification of a test circuit, or complicated post-data analysis. Therefore, de-skew has always been a headache for engineers who evaluate the dynamic characteristics of power devices.

A first method described by Zhang includes applying a power measurement de-skew and calibration fixture. This method is convenient, but suffers the drawback of being less compatible due to the connector constraints. That is, a special fixture is needed to perform de-skew, and creating such a fixture is not always easy. In addition, only current probes from Tektronix can be de-skewed with this fixture. Separately, its maximum allowable voltage is 8 Vrms, which is not suitable for the calibration of active probes with high dynamic range.

A second method described by Zhang uses a probe compensation output of the scope as a standard square waveform signal source for V-I alignment. In addition to the low input voltage (˜2.5V), another issue for this method is that only a coaxial cable rather than the combination of coaxial cable and shunt is de-skewed, which will induce timing misalignment in the switching current measurement. While this second method is relatively easy to perform, it suffers from reduced accuracy as it does not de-skew the delay of the current sensor (current shunt, current transformer, etc.).

A third method described by Zhang entails removing an inductor in a double pulse test (DPT) and replacing it with a low inductance 100Ω resistor. In this resistive load DPT, the voltage across a pure resistor is 100× of the current through it, with negligible phase shift induced by the extremely small ratio between series inductance and resistance (˜50 ps in practice). The maximum input voltage is determined by the resistor, usually several hundred volts. A drawback with this method resides in the costs and inconvenience of modifying the test circuit.

A fourth method described by Zhang uses the actual DPT switching waveform based on known V-I relationships. During the di/dt of the turn-on transient, a voltage dip can be observed across the drain-source terminals of the operating device due to the parasitic inductance in the power loop. Thus, the current channel de-skew can be adjusted on the oscilloscope so that the initial drop in VDS is graphically aligned to the calculated voltage drop on the power loop inductance (i.e. Lds×dId/dt) during the turn-on transient. This method is most effective at high load current due to the longer di/dt transient duration. Because this method requires no external dedicated fixture or modification of the test circuit, this method for V-I alignment is preferred. If the magnitude of ringing or noise in the current or voltage channel is comparable to the actual magnitude of either waveform, this method can be difficult to implement. Therefore, it is helpful to adjust the dc offset and scale of both current and voltage channels to fill the entire oscilloscope screen during the di/dt transient time interval. This de-skew can also be performed during data processing, such as in MATLAB®, to verify V-I alignment in previously collected data. Nonetheless, this method is sometimes difficult to use because the voltage dip at the turn-on transient is not always clear. In addition, as the power loop inductance is not known before data analysis, the post-data processing to perform de-skew is a relatively complicated process. The result can vary depending on the person or algorithm that carries out the post-data processing.

Furthermore, all four methods fail to compensate for the frequency response of the current sensor. If the frequency response of the current sensor is not flat over the measurement bandwidth, the timing of a rising/falling edge of the current waveform varies, which results in misalignment of the voltage and the current waveforms. This issue becomes more impactful when evaluating high-frequency-response wide gap semiconductor (WBG) devices like GaN power transistors.

### SUMMARY

According to an aspect of the inventive concepts, a dynamic test method is provided which includes de-skewing first and second voltage probes and a current measurement cable connected to respective first, second and third channels of an oscilloscope. The method further includes configuring a dynamic test set-up of a device under test (DUT) including the oscilloscope, the de-skewed first and second voltage probes, and the de-skewed current measurement cable, wherein the dynamic test set-up further includes a current sensor connected between the DUT and the current measurement cable. The method further includes conducting a dynamic test of the DUT to obtain a current waveform displayed on the oscilloscope, and de-embedding the current waveform by using the oscilloscope to apply a transfer function of the current sensor to the current waveform to obtain a de-embedded current waveform displayed on the oscilloscope.

The de-skewing of the first and second voltage probes and the current measurement cable may include connecting one end of the first and second voltage probes and the current measurement cable to respective first, second and third channels of an oscilloscope, connecting another end of the first and second voltage probes to another end of the current measurement cable, and de-skewing the first and second voltage probes and the current measurement cable using the oscilloscope.

The de-skewing using the oscilloscope may be carried out using a square-wave signal.

The configuring the dynamic test set-up may include connecting the other end of the de-skewed first voltage probe to a first terminal of the DUT, connecting the other end of the de-skewed second voltage probe to a second terminal of the DUT, connecting an input of the current sensor to a third terminal of the DUT, connecting an output of the current sensor to the de-skewed current measurement cable, connecting a gate driver between the second terminal and third terminal of the DUT, and connecting the first terminal to a load element and a Free Wheeling Diode receiving a source voltage.

The first terminal of the DUT may be one of a drain electrode or a collector electrode, the second terminal of the DUT may be a gate electrode, and the third terminal of the DUT is one of a source electrode or an emitter electrode. The DUT may be a power transistor, such as a GaN power transistor.

The transfer function of the current sensor may be determined in advance, and may be determined using a vector network analyzer.

According to another aspect of the inventive concepts, a dynamic test method includes configuring a dynamic test set-up for a device under test (DUT), the dynamic test set-up including at least one de-skewed voltage probe and at least one de-skewed current measurement cable connected to respective channels of an oscilloscope, and a current sensor connected to the de-skewed current measurement cable and configured to measure a current of the DUT. The method further includes conducting a dynamic test set-up for the DUT using the dynamic test set-up to obtain a current waveform for display on the oscilloscope, and applying a transfer function of the current sensor to the current waveform to display a corresponding de-embedded current waveform on the oscilloscope.

### BRIEF DESCRIPTION OF THE DRAWINGS

The above and other aspects and features of the inventive concepts will become readily apparent from the detailed description that follows, with reference to the accompanying drawings, in which:

FIG. 1 is a flow-chart for reference in describing a de-skew method according to embodiments of the inventive concepts;

FIG. 2 illustrates a circuit configuration for de-skewing voltage probes and a current measurement cable according to the de-skew method of FIG. 1;

FIGS. 3A and 3B show examples of displayed signal traces before and after the de-skewing of the voltage probes and the current measurement cable using the circuit configuration of FIG. 2;

FIG. 4 illustrates a circuit configuration for carrying out a dynamic test of a device under test (DUT) according to the de-skew method of FIG. 1;

FIG. 5 is a circuit diagram for reference in describing measurement of an S-parameter of a current sensor used in the circuit configuration of FIG. 4;

FIGS. 6 and 7 illustrate a measurement circuit and a simulation circuit for determining a transfer function of a current sensor used in the circuit configuration of FIG. 4;

FIGS. 8A and 8B show examples of displayed signal traces relating to a turn-on waveform of a GaN power transistor before and after de-embedding according to embodiments of the inventive concepts; and

FIGS. 9A and 9B show examples of displayed signal traces relating to a turn-on waveform of an SiC power transistor before and after de-embedding according to embodiments of the inventive concepts.

### DETAILED DESCRIPTION

In the following detailed description, for purposes of explanation and not limitation, representative embodiments disclosing specific details are set forth in order to provide a thorough understanding of an embodiment according to the present teachings. Descriptions of known systems, devices, materials, methods of operation and methods of manufacture may be omitted so as to avoid obscuring the description of the representative embodiments. Nonetheless, systems, devices, materials and methods that are within the purview of one of ordinary skill in the art are within the scope of the present teachings and may be used in accordance with the representative embodiments. It is to be understood that the terminology used herein is for purposes of describing particular embodiments only and is not intended to be limiting. The defined terms are in addition to the technical and scientific meanings of the defined terms as commonly understood and accepted in the technical field of the present teachings.

It will be understood that, although the terms first, second, third etc. may be used herein to describe various elements or components, these elements or components should not be limited by these terms. These terms are only used to distinguish one element or component from another element or component. Thus, a first element or component discussed below could be termed a second element or component without departing from the teachings of the present disclosure.

The terminology used herein is for purposes of describing particular embodiments only and is not intended to be limiting. As used in the specification and appended claims, the singular forms of terms “a,” “an” and “the” are intended to include both singular and plural forms, unless the context clearly dictates otherwise. Additionally, the terms “comprises,” and/or “comprising,” and/or similar terms when used in this specification, specify the presence of stated features, elements, and/or components, but do not preclude the presence or addition of one or more other features, elements, components, and/or groups thereof. As used herein, the term “and/or” includes any and all combinations of one or more of the associated listed items.

Unless otherwise noted, when an element or component is said to be “connected to,” “coupled to,” or “adjacent to” another element or component, it will be understood that the element or component can be directly connected or coupled to the other element or component, or intervening elements or components may be present. That is, these and similar terms encompass cases where one or more intermediate elements or components may be employed to connect two elements or components. However, when an element or component is said to be “directly connected” to another element or component, this encompasses only cases where the two elements or components are connected to each other without any intermediate or intervening elements or components.

The present disclosure, through one or more of its various aspects, embodiments and/or specific features or sub-components, is thus intended to bring out one or more of the advantages as specifically noted below. For purposes of explanation and not limitation, example embodiments disclosing specific details are set forth in order to provide a thorough understanding of an embodiment according to the present teachings. However, other embodiments consistent with the present disclosure that depart from specific details disclosed herein remain within the scope of the appended claims. Moreover, descriptions of well-known apparatuses and methods may be omitted so as to not obscure the description of the example embodiments. Such methods and apparatuses are within the scope of the present disclosure.

The inventive concepts are directed to de-skew techniques which may be considered an improvement upon the second method of Zhang previously described in the background section. In addition to implementing a relatively simple de-skew method using a square shape signal, the method applies a transfer function of the current sensor to a current waveform obtained during dynamic testing.

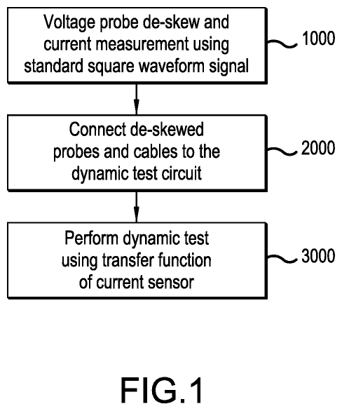

FIG. 1 is a flow chart for reference in describing a de-skew method for semiconductor device dynamic testing according to embodiments of the inventive concepts.

Referring to FIG. 1, initially, at step 1000, voltage probes and a current measurement cable are connected to channels of an oscilloscope, and are de-skewed using a standard square wave signal.

Then, at step 2000, a device under test (DUT) is connected in a dynamic test circuit configuration including drive circuitry, a current sensor, the oscilloscope, the voltage probes and the current measurement cable.

Then, at step 3000, a dynamic test of the DUT is preformed to obtain, among other things, a current waveform of the DUT. Also, a previously determined transfer function of the current sensor is applied to the obtained current waveform in a process referred to herein as “de-embedding”.

Each of steps 1000 to 3000 of FIG. 1 will be described below in greater detail.

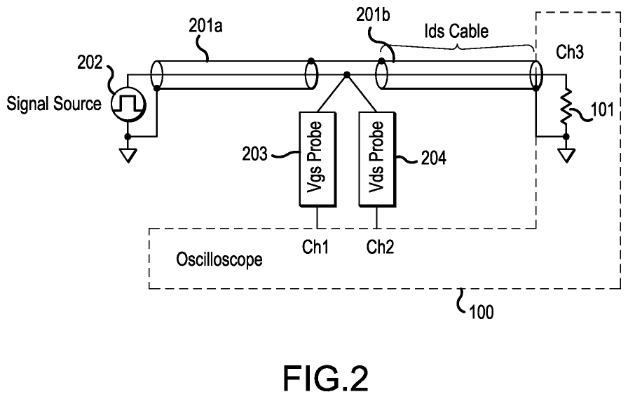

FIG. 2 illustrates a test set-up that may be utilized to carry out the first step 1000 of the de-skew method represented by FIG. 1.

Referring to FIG. 2, the test set-up of this example includes an oscilloscope 100 including multiple channels Ch1, Ch2 and Ch3. As shown, coaxial cables 201a and 201b connect a signal source 202 to a resistive termination 101 of the third channel Ch3 of the oscilloscope 100. In this example, the center conductor of the cables 201a/201b is connected to a grounded resistive termination 101 of the oscilloscope 100, and the outer conductor of the cables 201a/201b is connected to ground. In addition, a gate-source voltage (Vgs) (or gate-emitter voltage Vge)) probe 203 is connected between the first channel Ch1 and a center conductor along the length of the cables 201a/201b, while a drain-source voltage (Vds) (or collector-emitter voltage Vce)) probe 204 is connected between the second channel Ch2 and the center conductor along the length of the cables 201a/201b. The cable 201b between the probe 203/204 connections and channel Ch3 may be considered a current measurement (Ids) cable as represented in FIG. 2. As examples, the transmission line of the signal and the current measurement cable 201 may have a 50 ohm characteristic impedance and the resistive termination 101 may be a 50 ohm termination to avoid the signal reflection.

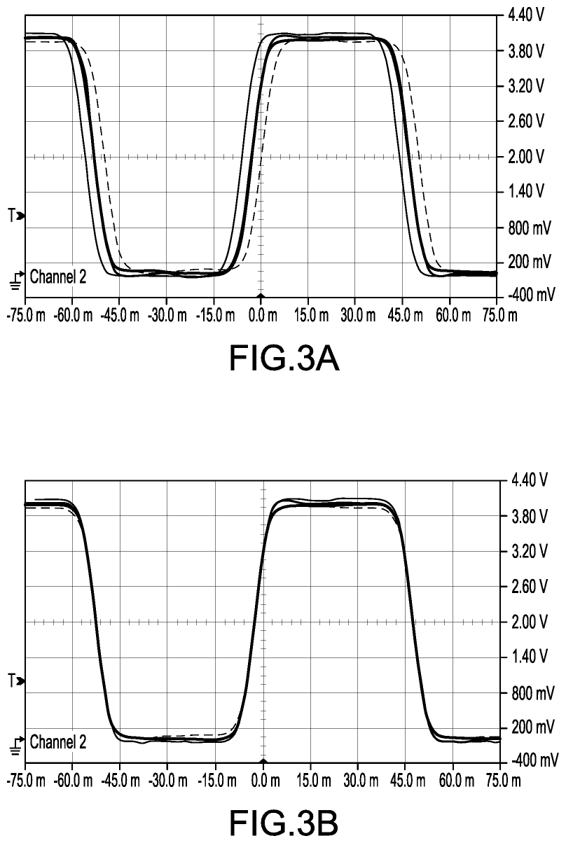

In step 1000 of FIG. 1, using the de-skew function of the oscilloscope 100 as set up in FIG. 2, de-skew is preformed (skew values are adjusted) using a standard square waveform signal for the voltage (Vgs or Vge) probe 203, the voltage (Vds or Vce) probe 204 and the current (Ids or Ice) measurement cable 201b. FIG. 3A illustrates an example of the corresponding signal traces observed on the oscilloscope display before de-skew. As can be seen in FIG. 3A, the observed signal traces are spaced apart to an extent. FIG. 3B illustrates an example of the corresponding signal traces observed on the oscilloscope display after de-skew. As can be seen in FIG. 3B, the observed signal traces are made to overlap as a result of the de-skew process of step 1000.

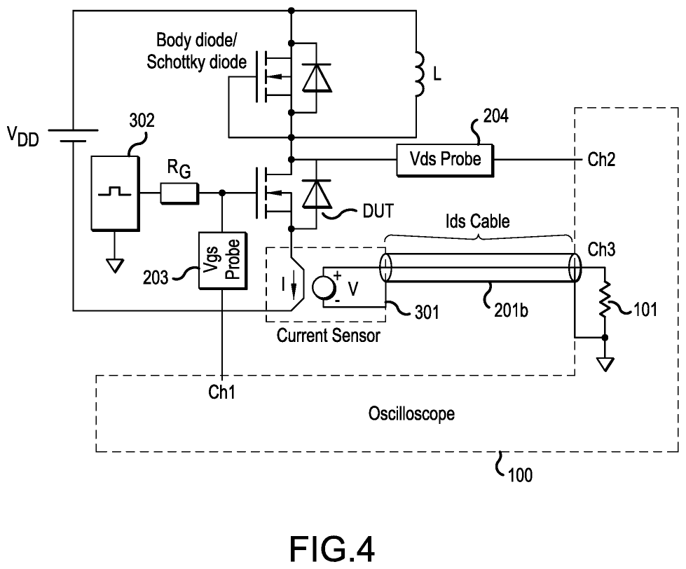

Next, in step 2000 of FIG. 1, the de-skewed probes 203/204 and Ids cable 201b are connected to a dynamic test circuit. FIG. 4 is a circuit diagram illustrating an example of the resultant test set-up.

Referring to FIG. 4, the Vgs probe 203 is directly connected to a gate of a device under test (DUT), and the Vds probe 204 is directly connected to a drain of the DUT. A current sensor 301 is connected to a source of the DUT and generates a voltage V according to a currently flowing through the DUT. The Ids cable 201b is connected to receive the voltage V of the current sensor 301. During testing, the DUT is driven by a voltage source V_{DD} and a gate driver 302 connected to a gate terminal R_{G}. In the figure, L denotes a load inductor of the circuit. The load inductor L constitutes a load element, which instead can be a resistive load. The Schottky diode (or body diode) as shown is typically referred to as a Free Wheeling Diode (FWD) because it allows the current from the load inductor L to flow like a freewheel while the DUT is off.

Next, in step 3000 of FIG. 1, a dynamic test is carried out with the hardware configuration of FIG. 4 described above. As a result, a number of signal traces including a current (Ids or Ice) waveform are obtained. Also in step 300, a transfer function of the current sensor 301 is applied to the obtained current (Ids or Ice) waveform. This is referred to herein as “de-embedding”.

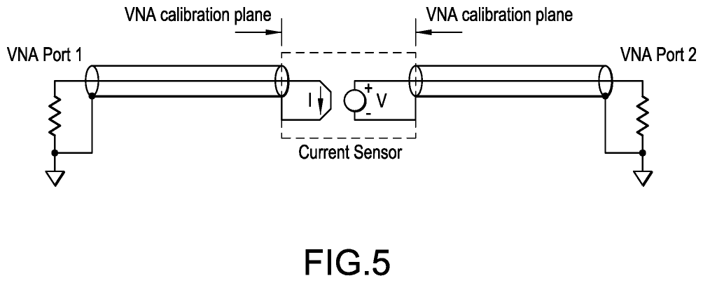

The transfer function of the current sensor 301 may be determined in advance before the dynamic test. Referring to FIG. 5, to obtain the transfer function, first the 2-port S-parameter of the current sensor 301 is measured via a 2-port vector network analyzer (VNA). The S-parameter can be measured by connecting the current input port of the sensor 301 to VNA port 1, and the voltage output port of the sensor 301 to VNA port 2. The calibration plane of the VNA is on both terminals of the current sensor as shown in FIG. 5.

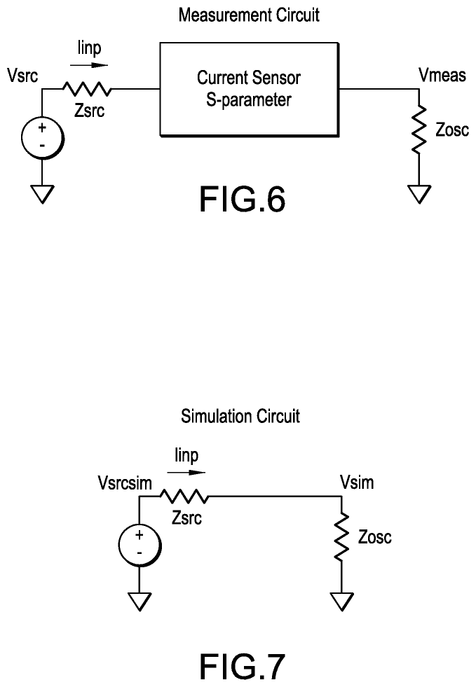

After the S-parameter is measured, the transfer function of the current sensor 301 can be calculated by comparing the actual measurement circuit (FIG. 6) represented by the S-parameter and an ideal simulation circuit (FIG. 7). By assuming the measurement and simulation circuit shown in FIGS. 6 and 7, the following transfer function may be obtained:

H(f)=Vsim(f)/Vmeas(f).

When Zsrc is sufficiently bigger than input impedance of the current sensor, the following can be assumed:

Vsrcsim˜Vsrc*(Zsrc+Zosc)/Zsrc.

De-embedding of the current waveform may be done by the inverse Fourier transform and convolution functionality provided by the oscilloscope 100.

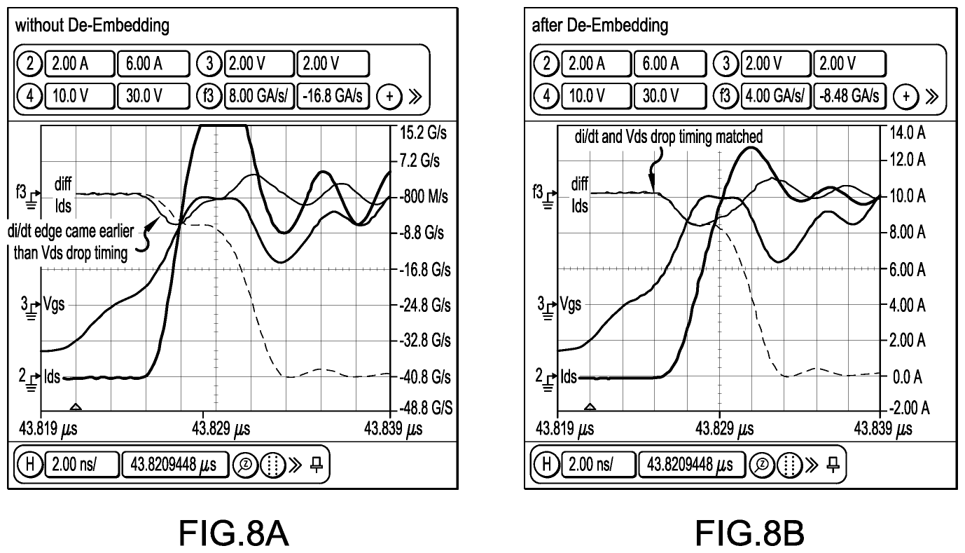

Take current shunts as an example. Current shunts usually have a parasitic inductance (Ls) in series with the shunt resistor. This parasitic inductance gives additional voltage Ls*di/dt to the observed waveform, and consequently, the observed turn-on/off current waveform appears to be rising/falling earlier than the actual current waveform. In this respect, attention is directed to FIG. 8A which is an actual turn-on waveform of a GaN power transistor before de-embedding, and FIG. 8B which shows the same after de-embedding. The Vds waveform shown in red clearly shows voltage dip caused by power loop inductance and di/dt of the drain current. Theoretically, di/dt and the dip in Vds must be proportional. However, looking at the waveform without de-embedding, the edge of di/dt comes earlier than Vds drop, indicating the effect of parasitic inductance in the current shunt. By applying de-embedding of the current shunt, the timing of di/dt edge and Vds drop match as shown in FIG. 8B, and they became proportional, establishing that an accurate de-skew was achieved.

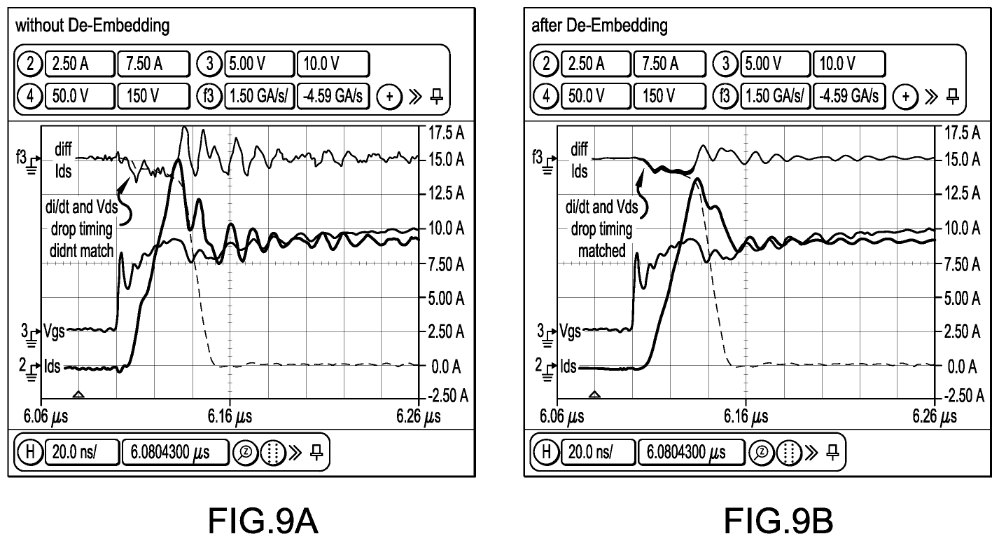

Similar results are demonstrated in FIGS. 9A and 9B with respect to SiC power transistors. That is, FIG. 9A is an actual turn-on waveform of a GaN power transistor before de-embedding, and FIG. 9B shows the same after de-embedding.

The inventive concepts described above offer a number of advantages. First, special fixtures are not required to perform de-skew, and alterations of the dynamic test circuit are not required. In addition, the de-skew techniques allow for the use of industry-standard post-data processing, i.e., the algorithms are already built in the software of commercially available oscilloscopes. Further, the inventive concepts compensate for the frequency response of the current sensor, which provides for increased accuracy.

It is necessary to know the S-parameter of the current sensor. However, the S-parameter of the current sensor does not vary significantly over time. As such, the measurement of the S-parameter may occur only occasionally, e.g., once a year or so.

The above-described embodiments of the present invention have been provided to illustrate various aspects of the invention. However, it is to be understood that different aspects of the present invention that are shown in different specific embodiments can be combined to provide other embodiments of the present invention. In addition, various modifications to the present invention will become apparent from the foregoing description and accompanying drawings. Accordingly, the present invention is to be limited solely by the scope of the following claims.

What is claimed is:

1. A dynamic test method, comprising:
de-skewing first and second voltage probes and a current measurement cable connected to respective first, second and third channels of an oscilloscope;
configuring a dynamic test set-up of a device under test (DUT) including the oscilloscope, the de-skewed first and second voltage probes, and the de-skewed current measurement cable, wherein the dynamic test set-up further includes a current sensor connected between the DUT and the current measurement cable;
conducting a dynamic test of the DUT to obtain a current waveform displayed on the oscilloscope; and
de-embedding the current waveform by using the oscilloscope to apply a transfer function of the current sensor to the current waveform to obtain a de-embedded current waveform displayed on the oscilloscope.

2. The dynamic test method of claim 1, wherein de-skewing the first and second voltage probes and the current measurement cable includes:
connecting one end of the first and second voltage probes and the current measurement cable to respective first, second and third channels of an oscilloscope;
connecting another end of the first and second voltage probes to another end of the current measurement cable;
de-skewing the first and second voltage probes and the current measurement cable using the oscilloscope.

3. The dynamic test method of claim 2, wherein de-skewing using the oscilloscope is carried out using a square-wave signal.

4. The dynamic test method of claim 1, wherein configuring the dynamic test set-up includes:
connecting the other end of the de-skewed first voltage probe to a first terminal of the DUT;
connecting the other end of the de-skewed second voltage probe to a second terminal of the DUT;
connecting an input of the current sensor to a third terminal of the DUT;
connecting an output of the current sensor to the de-skewed current measurement cable;
connecting a gate driver between the second terminal and third terminal of the DUT; and
connecting the first terminal to a load element and a Free Wheeling Diode.

5. The dynamic test method of claim 4, wherein the first terminal of the DUT is one of a drain electrode or a collector electrode;
the second terminal of the DUT is a gate electrode; and
the third terminal of the DUT is one of a source electrode or an emitter electrode.

6. The dynamic test method of claim 5, wherein the DUT is power transistor.

7. The dynamic test method of claim 6, wherein the DUT is a GaN power transistor.

8. The dynamic test method of claim 1, wherein the transfer function of the current sensor is determined in advance.

9. The dynamic test method of claim 8, wherein the transfer function of the current sensor is determined using a vector network analyzer.

10. A dynamic test method comprising:
configuring a dynamic test set-up for a device under test (DUT), the dynamic test set-up including at least one de-skewed voltage probe and at least one de-skewed current measurement cable connected to respective channels of an oscilloscope, and a current sensor connected to the de-skewed current measurement cable and configured to measure a current of the DUT;
conducting a dynamic test set-up for the DUT using the dynamic test set-up to obtain a current waveform for display on the oscilloscope; and
applying a transfer function of the current sensor to the current waveform to display a corresponding de-embedded current waveform on the oscilloscope.
